(19) United States
(12) Patent Application Publication
(10) Pub. No.: US 2008/0076259 A1
(43) Pub. Date: Mar. 27, 2008

(54) Plasma Etching Method

(76) Inventors: Yoshiyuki OOTA, Kudamatsu-shi (JP); Tsuyoshi Yoshida, Hikari-shi (JP); Eiji Ikegami, Kudamatsu-shi (JP); Kenji Imamoto, Hikari-shi (JP); Jyunji Adachi, Hofu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/622,525

(22) Filed: Jan. 12, 2007

(30) Foreign Application Priority Data
Sep. 25, 2006 (JP) 2006-259331

(51) Int. Cl. H01L 21/461; H01L 21/302

(52) U.S. Cl. 438/706; 438/710; 438/723

(57) ABSTRACT

The invention provides a plasma etching method that does not create any difference in profile between sparse and dense portions of the mask pattern in processing a device having a space width equal to or smaller than 100 nm. An added gas having a high C/F ratio such as C₄F₈ gas capable of increasing the generation of CF₂ radicals that may become sidewall protection film components having a small attachment coefficient is added to the etching gas in order to form sidewall protection films on dense pattern portions, and in addition, Xe gas is added in order to suppress dissociation effect by lowering the electron temperature.

The present application is based on and claims priority of Japanese patent application No. 2006-259331 filed on Sep. 25, 2006, the entire contents of which are hereby incorporated by reference.

### BACKGROUND OF THE INVENTION

1. Field of the Invention

The present invention relates to a plasma etching method capable of forming a superior gate mask of microscopic dimension in the gate mask processing of a device having a space width of 100 nm or smaller in the method of manufacturing a semiconductor device having a line and space pattern patterned thereon.

2. Description of the Related Art

Along with the further integration and speeding up of recent semiconductor integrated circuits, there are demands for further miniaturization of gate masks (masks for processing gate electrodes). In a process profile for forming a mask pattern in which line and space appear alternately, it is required that there is no profile difference in the finished mask regardless of the denseness or sparseness of the mask pattern or between a dense portion having a small space ratio and a sparse portion having a large space ratio. As for the device in which a space width of the mask pattern is 100 nm or greater, it is possible to process a mask having no profile difference regardless of the sparseness or denseness of the mask pattern by the prior art etching method, but as for the device having a space width of 100 nm or smaller, there is a drawback in that a difference in profile of the mask occurs depending on the sparseness or denseness of the mask pattern when processing is performed by the prior art etching method.

According to the prior art etching method, etching is performed using a gas formed by mixing CF₄, CHF₃ and inert gas such as Ar (refer for example to Japanese Patent Application Laid-Open Publication No. 2006-32801, hereinafter referred to as patent document 1), but in processing a gate mask having increased aspect ratio due to the miniaturization of the mask pattern, it has become difficult to reduce the difference in mask profile between the sparse and dense portions of the mask pattern. In the prior art etching method, gases such as CF₄, CHF₃, CH₂F₂ and CH₃F are used as the etching gas. These etching gases generate C radicals and F radicals in the plasma, causing the C radicals having a high attachment coefficient to be attached to a sparse pattern portion having a large angle of attack, by which the profile of the sparse portion becomes a forward tapered shape, whereas in the dense pattern portion, the sidewall protection film components required to protect the side walls of the dense pattern portion are unable to reach the side walls due to the increased aspect ratio by the miniaturization and integration of the pattern, by which a side etch is caused, creating a difference in the mask profile between the sparse portion and the dense portion.

Now, the definition of the difference in profile between the sparse portion and the dense portion of the mask will be described with reference to FIG. 3. The processing substrate is formed by providing in multiple layers on a surface of a Si substrate 409 a silicon oxide film (SiO₂), a polysilicon layer (Poly-Si) 407, a tungsten silicon film (WSi) 406, a silicon nitride film (SiN) 405, an organic film interlayer 404, an inorganic film interlayer 403 and a BARC 402, and then forming thereon an ArF resist film (hereinafter sometimes simply referred to as resist) 401, and subjecting the same to patterning. The line width dimension of the resist 401 prior to etching in a dense pattern portion in which the pattern density is high is referred to as A, and the line width dimension of the resist 401 prior to etching in a sparse pattern portion in which the pattern density is low is referred to as B.

Using the resist 401 having line width dimensions A and B as the mask, the silicon nitride film 405 disposed below the mask is etched. At this time, the line width dimension of the dense pattern portion 405 after etching is referred to as AA, and the line width dimension of the sparse pattern portion 405 after etching is referred to as BB. The difference in dimension prior to and after etching of the dense pattern portion is represented by (AA−A), and the difference in dimension prior to and after etching of the sparse pattern portion is represented by (BB−B). The difference between (AA−A) and (BB−B) is presented as a sparse-dense dimension difference.

In other words, the sparse-dense dimension difference is expressed by the following expression (1).

|Sparse-dense dimension difference|=(BB−B)−(AA−A) (1)

As described, the area in which the pattern density is high is etched in the state of a side etch (FIGS. 3(A) AA), and the area in which the pattern density is low is etched in a forward tapered shape (FIGS. 3(B) BB). This property becomes apparent when the space width is equal to or smaller than 100 nm, disadvantageously affecting the subsequent processes.

### SUMMARY OF THE INVENTION

In view of the prior art problems mentioned above, the present invention aims at providing a plasma etching method of a semiconductor integrated circuit capable of reducing the difference in profile occurring between the sparse portion and the dense portion of the mask pattern and ensuring a good process profile and mask selectivity upon forming a mask for processing a microscopic gate electrode using SiN (silicon nitride film) or SiO₂ (silicon oxide film) from 65 nm node onward using a multilayer resist mask structure.

In order to solve the problems of the prior art, the present invention increases the generation of CF₂ radicals having a small attachment coefficient and may become sidewall protection film components, in order to form sidewall protection films in the dense pattern portion. Furthermore, in order to increase the generation of CF₂ radicals, a gas having a high C/F ratio such as C₄F₈ gas is added with the aim to increase the CFx radical source and/or Xe gas is added with the aim to suppress the dissociation effect by lowering the electron temperature.

In order to solve the above-mentioned problem, the present invention provides a plasma etching method for etching using a plasma generated by etching gas a line and space (L/S) pattern on a silicon oxide film and a silicon nitride film using a multilayer resist mask, wherein a diluent gas is added to the etching gas in order to suppress excessive dissociation of the etching gas.

The present invention provides the above-mentioned plasma etching method, wherein an etching gas composed of CF₄, CHF₃, CH₂F₂, CH₃F or the like is used as the etching gas, and a gas for lowering an electron temperature of the plasma such as Xe gas or Kr gas is added as the diluent gas in order to suppress excessive dissociation of the etching gas. At this time, the additive amount of diluent gas is set to fall within the range of 0.2 to 10.0 with respect to 1.0 etching gas.

The present invention further provides a plasma etching method for etching using plasma generated by etching gas a line and space (L/S) pattern on a silicon oxide film and a silicon nitride film using a multilayer resist mask, wherein the ratio of CF₂ radicals having a low attachment coefficient is increased.

The present invention provides the above-mentioned plasma etching method, wherein an etching gas composed of CF₄, CHF₃, CH₂F₂, CH₃F or the like is used as the etching gas, and a gas having a high C/F ratio compared to the etching gas, such as C₄F₆, C₄F₈ and C₅F₈, is added in order to increase the ratio of CF₂ radicals having a low attachment coefficient. At this time, the additive amount of the gas having a high C/F ratio is set to fall within the range of 0.01 to 0.5 with respect to 1.0 etching gas.

The present invention provides a plasma etching method for etching using a plasma generated using etching gas a line and space (L/S) pattern on a silicon oxide film and a silicon nitride film using a multilayer resist mask, wherein an etching gas composed of CF₄, CHF₃, CH₂F₂, CH₃F or the like is used as the etching gas; a gas for lowering an electron temperature of the plasma such as Xe gas or Kr gas is added as the diluent gas in order to suppress excessive dissociation of the etching gas, and a gas having a high C/F ratio compared to the etching gas, such as C₄F₆, C₄F₈ and C₅F₈, is added in order to increase the ratio of CF₂ radicals having a low attachment coefficient.

The present invention provides the above-mentioned plasma etching method, wherein a source power applied to the plasma is lowered in order to suppress excessive dissociation of the etching gas. Furthermore, the present invention provide the above-mentioned plasma etching method, wherein an ArF resist film is used as the resist mask.

According to the present invention, it becomes possible to reduce the difference in profile between sparse and dense portions while ensuring a good process profile in the process of forming a microscopic hard mask using SiN (silicon nitride film) or SiO₂ (silicon oxide film) from 65 nm node onward using a multilayer resist mask structure.

### BRIEF DESCRIPTION OF THE DRAWINGS

FIG. 1 is an explanatory view showing the structure of a multi-chamber plasma etching apparatus for realizing the present invention;

FIG. 2 is a cross-sectional view illustrating the structure of a processing chamber of the multi-chamber plasma etching apparatus for realizing the present invention;

FIG. 3 is a view illustrating the sparse-dense profile difference according to the present invention;

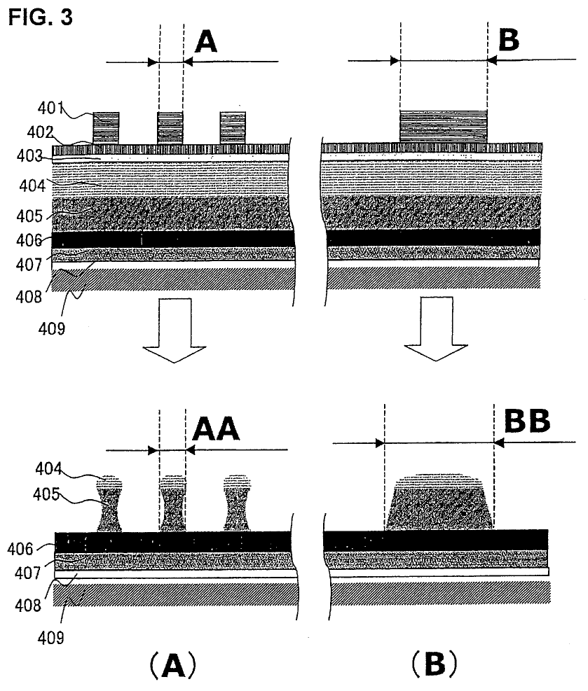

FIGS. 4A, 4B, 4C and 4D are views illustrating the process flow according to the present invention; and

FIGS. 5A, 5B and 5C are views illustrating the process parameter dependency according to the present embodiments.

### DETAILED DESCRIPTION OF THE PREFERRED EMBODIMENTS

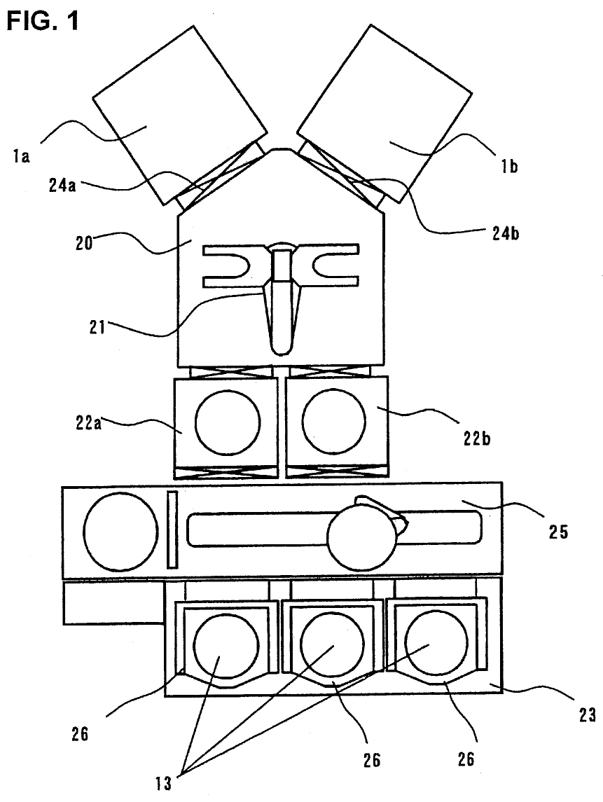

Now, the structure of a plasma etching apparatus to which the plasma etching method according to the present invention is applied will be described with reference to FIG. 1. FIG. 1 is a plan view of a plasma etching apparatus including a single-wafer multichamber used for the present invention. The plasma etching apparatus is composed of a vacuum transfer chamber 20 equipped with a vacuum transfer robot 21, two or more processing chambers 1a and 1b connected to the vacuum transfer chamber 20 via gates 24a and 24b, load lock chambers 22a and 22b disposed between the vacuum transfer chamber 20 and an atmospheric loader unit 25, an atmospheric loader unit 25, and a cassette mounting unit 23 for mounting the wafer cassettes 26. The plasma etching apparatus is capable of subjecting processing substrates 13 either to identical processes in parallel in the vacuum processing chambers 1a and 1b or to different processes sequentially in vacuum processing chambers 1a and 1b.

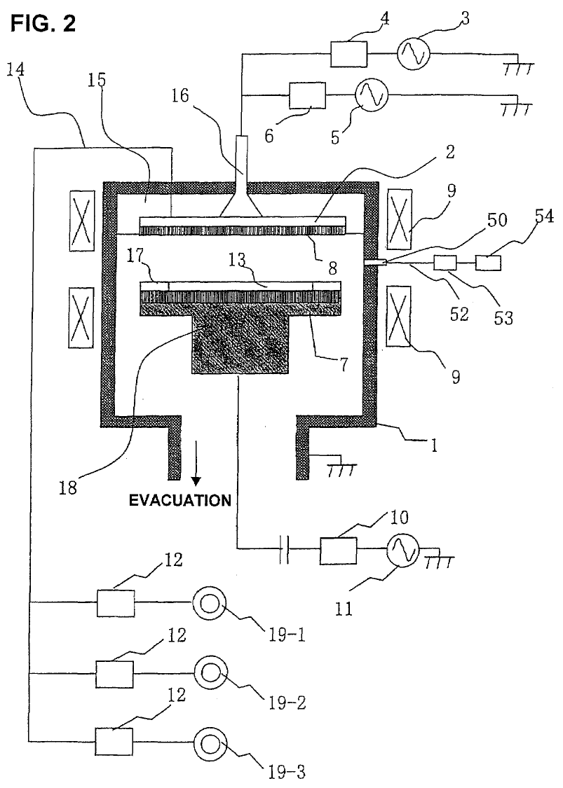

Since the vacuum processing chambers 1a and 1b of the plasma etching apparatus are designed substantially identically, the details of the vacuum processing chamber 1 is described in detail with reference to FIG. 2. The illustrated plasma etching apparatus is an UHF plasma etching apparatus in which ultra high frequency (UHF) and magnetic field are applied to generate plasma.

The vacuum processing chamber 1 is a vacuum vessel having coils 9 surrounding the vessel to generate a magnetic field for electron cyclotron resonance (ECR), and the temperature of the inner wall of the chamber is controlled to 30° C. via a temperature regulator (not shown). The processing substrate 13 is mounted on a substrate electrode 18 provided with an electrostatic chuck 7. A DC power supply (not shown) is connected to the electrostatic chuck 7 to attract the processing substrate 13 to the electrostatic chuck 7. A focus ring 17 is disposed on the upper circumference of the electrostatic chuck 7. A substrate bias power supply 11 is connected via a matching box 10 to the substrate electrode 18, enabling high-frequency bias to be applied to the processing substrate 13.

Chlorofluorocarbon such as CF₄, CHF₃ and CH₂F₂ which are used conventionally as main etching gases; added gases having high C/F ratio such as C₂F₆, C₃F₈, C₄F₆, C₄F₈ and C₅F₈; and inert gases such as Ar, Xe and Kr are fed respectively from gas cylinders 19-1, 19-2 and 19-3, the flow rate of which are controlled via mass flow controllers 12, and introduced via a gas supply pipe 14 connected to process gas sources and through a gas supply plate 8 formed of silicon or glassy carbon having a large number of gas holes formed thereon to the processing chamber 1a.

An antenna electrode 2 is disposed above the gas supply plate 8. High-frequency power is fed from a high-frequency power supply 3 and a high-frequency power supply 5 via matching circuits 4 and 6 and via a coaxial terminal 16 to the antenna electrode 2. High frequency power is irradiated through a dielectric window 15 disposed around the antenna electrode 2 into the processing chamber 1, and simultaneously, a resonance electric field is introduced via the gas supply plate 8 to the processing chamber 1, by which plasma is generated to subject the processing substrate 13 to etching process.

On the lower area of the vacuum processing chamber 1 are disposed an evacuation means (not shown) composed of a turbo-molecular pump (TMP) and a pressure control means (not shown) composed of an automatic pressure controller (APC), by which the chamber is maintained at predetermined pressure while evacuating the etching gas from the vacuum processing chamber 1 after processing. A quartz window 50 is provided on the circumferential wall of the vacuum processing chamber 1, through which the emitting condition with in the vacuum processing chamber is sent via an optical fiber 52 to a spectrometer 53, and the emitting condition within the vacuum processing chamber is computed via a data processing unit 54.

### Embodiment 1

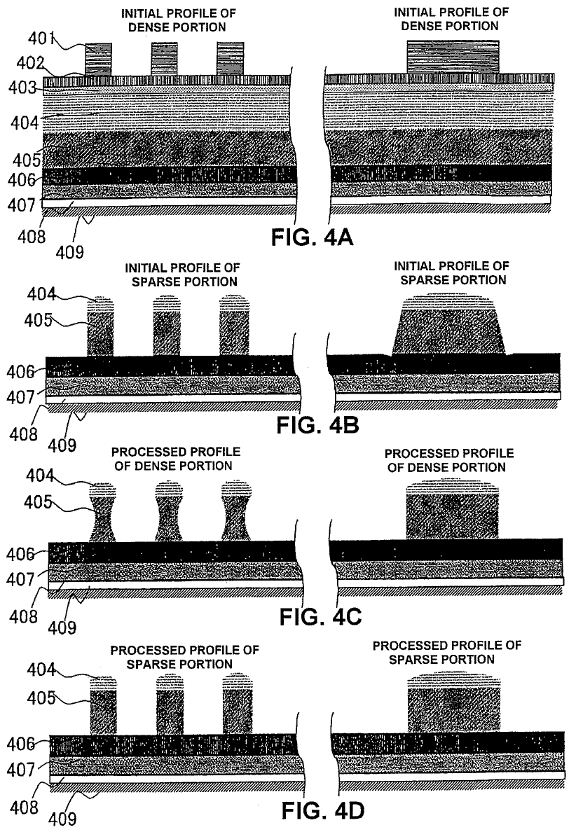

Now, a first embodiment of the present invention will be described with reference to FIGS. 4A through 4D. FIG. 4A shows the initial profile. FIG. 4B shows an example in which a silicon nitride film 405 of a dense pattern portion is subjected to plasma etching having high verticalness using a main gas chemistry of a prior art plasma etching method, which are CF₄, CHF₃, CH₂F₂, CH₃F and the like. FIG. 4C shows an example in which a silicon nitride film 405 of a sparse pattern portion is subjected to plasma etching having high verticalness using a main gas chemistry of a prior art plasma etching method, which are CF₄, CHF₃, CH₂F₂ and the like. FIG. 4D illustrates etching profiles obtained by the present method.

As illustrated in FIG. 4B, if the silicon nitride film 405 of a dense pattern portion is subjected to plasma etching having high verticalness using a main gas chemistry of a prior art plasma etching method, which are CF₄, CHF₃, CH₂F₂, CH₃F and the like, it becomes possible to obtain a vertical profile in the dense pattern portion, but the profile of the silicon nitride film 405 of the sparse pattern portion becomes a forward tapered shape. Further, as illustrated in FIG. 4C, if the silicon nitride film 405 of a sparse pattern portion is subjected to plasma etching having high verticalness using a main gas chemistry of a prior art plasma etching method, which are CF₄, CHF₃, CH₂F₂ and the like, side etch occurs to the silicon nitride film 405 of the dense pattern portion. As described, according to the prior art plasma etching method, there is a difference between the amount of sidewall protection film components (radicals) supplied to the side walls of the sparse portion and the dense portion, so that differences in size and profile occur between the sparse portion and the dense portion.

In order to realize plasma etching in which the silicon nitride film 405 are vertical in both the dense pattern portion and the sparse pattern portion and no difference in size and profile occurs between the sparse area and the dense area, as shown in FIG. 4D, the present invention adds Xe gas or Kr gas to the main gas chemistry of the prior art plasma etching method, which are CF₄, CHF₃, CH₂F₂, CH₃F and the like. The object of adding Xe gas or Kr gas is to lower the electron temperature by adding the Xe gas or the Kr gas. By suppressing plasma dissociation (reducing plasma density) by lowering the electron temperature, it becomes possible to expect the increase of ratio of CF₂ radicals/C₂ radicals, by which the growth of sidewall protection film components necessary to protect the side walls of the dense pattern portion is promoted so as to prevent the occurrence of a side etch.

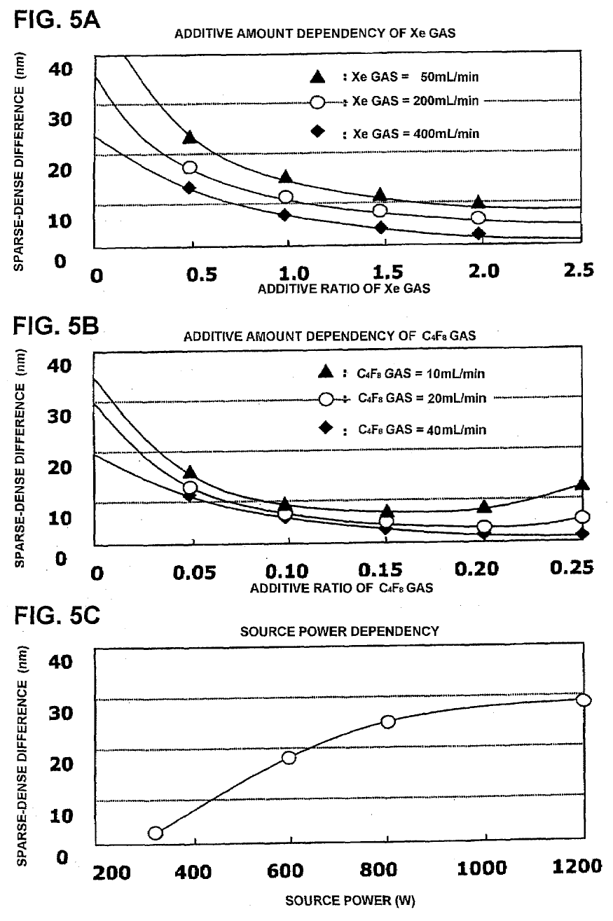

As a result, as shown in FIG. 5A, the dense-sparse difference is reduced as the added amount of Xe gas is increased. This is because the electron temperature of plasma reduces by adding Xe gas, by which dissociation is suppressed, the CF₂/C₂ radical ratio in the plasma is increased, and the CF₂ radicals having a small attachment coefficient reach the side walls of the dense pattern having a high aspect ratio, according to which the sidewall protection effect is achieved. As for the gas ratio at this time, it is desirable that the added amount of Xe gas or Kr gas is within the range of 0.2 through 10.0 with respect to 1.0 main etching gas according to the prior art plasma etching method. Furthermore, it is desirable that the pressure within the processing chamber is within the range of 0.1 through 20.0 Pa.

### Embodiment 2

As described in embodiment 1, the aforementioned problems occur according to the prior art plasma etching method. In order to realize etching having high verticalness both in sparse and dense pattern portions, a C₄F₈ gas is added to the main gas chemistry of the prior art etching, which are CF₄, CHF₃, CH₂F₂, CH₃F and the like. The object of adding C₄F₈ gas is to provide a source for supplying CF₂ radicals acting as side wall protection film components of the dense pattern portion.

As a result, the sparse-dense difference is reduced as the additive amount of C₄F₈ gas is increased, as shown in FIG. 5B. Since the amount of CF₂ radicals are increased by adding C₄F₈ gas, it is considered that CF₂ radicals having small attachment coefficient enter the dense pattern portion having a small angle of attack, according to which a side wall protection effect is achieved. It is preferable that the gas ratio at this time is set so that the additive amount of C₄F₈ gas is approximately 0.01 to 0.5 with respect to 1.0 main etching gas of the prior art plasma etching method. In addition, it is preferable that the pressure within the plasma processing chamber is 0.1 to 20.0 Pa.

### Embodiment 3

As described in embodiment 1, the aforementioned problems occur according to the prior art plasma etching method. In the present embodiment, in order to realize an etching having high verticalness in both sparse and dense pattern portions, a high-frequency power zone lower than the prior art plasma etching method is utilized.

As a result, as shown in FIG. 5C, as the high-frequency power is lowered, the sparse-dense difference is reduced. This is because dissociation is suppressed along with the lowering of the high-frequency power, and the CF₂ radical ratio of the plasma is increased, according to which the CF₂ radicals having a small attachment coefficient reach the side walls of the dense pattern portion having a high aspect ratio, and the effect of protecting the side walls is achieved.

By combining the addition of Xe gas, the addition of C₄F₈ gas and the application of low high-frequency power zone according to embodiments 1, 2 and 3, it becomes possible to establish a plasma etching method capable of further promoting the generation of CF₂ radicals.

In addition, by utilizing the above-mentioned plasma etching method, it becomes possible to establish a plasma etching method capable of performing processing without causing deformation or deterioration of the ArF resist generally considered to have low resistance to plasma. This is because according to the present invention, the generation of CF₂ radicals is promoted compared to the prior art plasma etching method, which enables the processing to be performed while protecting the ArF resist.

1. A plasma etching method for etching a line and space (L/S) pattern on a silicon oxide film and a silicon nitride film having a dense pattern portion and a sparse pattern portion, using a multilayer resist mask, wherein
an etching gas composed of CF₄, CHF₃, CH₂F₂, CH₃F is used as the etching gas:
a gas for lowering an electron temperature of the plasma, of Xe gas or Kr gas, is added as a diluent gas in order to suppress excessive dissociation of the etching gas; a gas having a high C/F ratio compared to the etching gas, of C₄F₆, C₄F₈ and C₅F₈, is added in order to generate CF₂ radicals having a low attachment coefficient; and
the diluent gas is added to the etching gas in order to suppress excessive dissociation of the etching gas and/or to increase the ratio of CF₂ radicals having a low attachment coefficient so that the dense pattern portion and the sparse pattern portion are worked uniformly.

2. (canceled)

3. The plasma etching method according to claim 1, wherein
an additive amount of diluent gas is set to fall within the range of 0.2 to 10.0 with respect to 1.0 etching gas.

4. (canceled)

5. The plasma etching method according to claim 1, wherein
an additive amount of the gas having a high C/F ratio falls within the range of 0.01 to 0.5 with respect to 1.0 etching gas.

6. (canceled)

7. The plasma etching method according to claim 1, wherein
a source power applied to the plasma is lowered in order to suppress excessive dissociation of the etching gas.

8. The plasma etching method according to claim 1, wherein a pressure within a plasma processing chamber in which said plasma etching method is conducted, is 0.1 to 20.0 Pa.
